(19) United States
(12) Patent Application Publication
(10) Pub. No.: US 2012/0326200 A1
(43) Pub. Date: Dec. 27, 2012

(54) FLIP-CHIP LIGHT EMITTING DIODE AND METHOD FOR MAKING THE SAME

(75) Inventors: CHIA-HUI SHEN, Hukou (TW); TZU-CHIEN HUNG, Hukou (TW)

(73) Assignee: ADVANCED OPTOELECTRONIC TECHNOLOGY, INC., Hsinchu Hsien (TW)

(21) Appl. No.: 13/452,963

(22) Filed: Apr. 23, 2012

(30) Foreign Application Priority Data
Jun. 22, 2011 (CN) 201110169450.X

(51) Int. Cl. H01L 33/62

(52) U.S. Cl. 257/99; 438/26; 257/E33.062

(57) ABSTRACT

A flip-chip light emitting diode comprising: a substrate; a circuit layer formed on the substrate, the circuit layer comprising a first electrode and a second electrode separated and electrically insulated from the first electrode; an LED chip arranged on the circuit layer, the LED chip comprising a positive electrode and a negative electrode, the positive electrode and the negative electrode which are located at a bottom face of the LED chip being in electrical connection to the first electrode and the second electrode of the circuit layer by solder, respectively; and a blocking structure located between the positive electrode and the negative electrode, the blocking structure being made of elastic and electrically insulating, colloidal material.

### TECHNICAL FIELD

The present disclosure relates to a semiconductor structure, and more particularly, to a flip-chip LED and method for making the same.

### DESCRIPTION OF RELATED ART

LEDs are generally packaged by flip-chip in present LED packaging process, in which two electrodes of the LED chip are directly soldered to electrodes of a substrate. However, during the soldering, the melted solder is likely to flow to a position between the two electrodes of the LED chip, which undesirably causes a short circuit of the LED.

Therefore, a flip-chip LED capable of overcoming the above described shortcoming is desired.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a schematic view of a flip-chip LED in accordance with an embodiment of the present disclosure.

FIG. 2 is a schematic view showing a mass of colloidal, electrically insulating material dropped on a substrate for making the flip-chip LED of FIG. 1.

### DETAILED DESCRIPTION

Embodiment of the present flip-chip LED and method for making the same will now be described in detail below and with reference to the drawings.

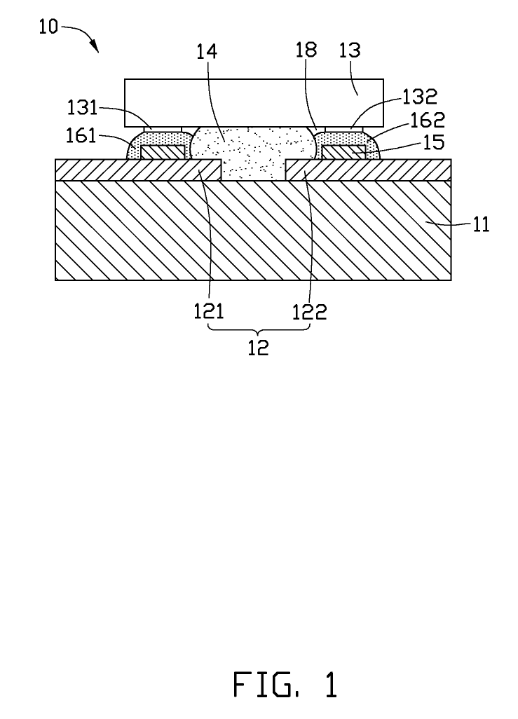

Referring to FIG. 1, a flip-chip LED 10 in accordance with an embodiment of the present disclosure includes a substrate 11, a circuit layer 12, an LED chip 13 and a blocking structure 14.

The substrate 11 is used for supporting the LED chip 13 thereon. The substrate 11 has a shape of a flat plate, and is made of silicon wafer.

The circuit layer 12 is formed on a top surface of the substrate 11. The circuit layer 12 includes a first electrode 121, a second electrode 122 separated and electrically insulated from the first electrode 121, and two metal shims 15 formed on top surfaces of the first electrode 121 and the second electrode 122, respectively. The metal shims 15 are arranged corresponding to electrodes 131, 132 of the LED chip 13, and used for positioning and supporting the LED chip 13. Alternatively, the metal shims 15 can be omitted.

The LED chip 13 is located on the circuit layer 12 of the substrate 11 by flip-chip. The LED chip 13 includes a positive electrode 131 and a negative electrode 132 on a bottom surface thereof and respectively corresponding to the first electrode 121 and the second electrode 122 of the circuit layer 12. The positive electrode 131 and the negative electrode 132 are electrically connected to the first electrode 121 and the second electrode 122 of the circuit layer 12 by a first solder 161 and a second solder 162 respectively. In this embodiment, when electrically connecting the LED chip 13 to the circuit layer 12, the first solder 161 and the second solder 162 are melted under high temperature and respectively flow around to cover the corresponding metal shims 15. As such, the positive electrode 131 and the negative electrode 132 are electrically connected to the first electrode 121 and the second electrode 122 of the circuit layer 12 respectively by the metal shims 15 and the first and second solders 161, 162. A room 18 is defined among the LED chip 13, the circuit layer 12, the first and second solders 161, 162 and the substrate 11.

The blocking structure 14 is formed on the substrate 11 and in the room 18. The blocking structure 14 is made of colloidal, electrically insulating material, which has good deformability but is capable of keeping a predetermined shape and not fractured or disintegrated under an external force since the blocking structure 14 has a certain degree of elasticity. In this embodiment, the blocking structure 14 is made of a mass of colloidal, high molecular polymer, such as sodium polyacrylate, polyacrylamide, carrageenan or gelatin. The blocking structure 14 is located between the first solder 161 and the second solder 162, and two opposite sides of the blocking structure 14 are connected to the first solder 161 and the second solder 162 respectively. The blocking structure 14 is generally hemispherical in its natural state, due to internal cohesion thereof. When the LED chip 13 is mounted onto the circuit layer 12, an apex of the blocking structure 14 which is slightly higher than top surfaces of the first solder 161 and the second solder 162 is depressed by a bottom surface of the LED chip 13 whereby the blocking structure 14 is laterally expanded. The blocking structure 14 is deformed by the LED chip 13 until the apex of the blocking structure 14 is coplanar with the top surfaces of the first solder 161 and the second solder 162. At this time, the blocking structure 14 is generally ellipsoidal, with a thickness thereof reduced in comparison with the natural state of the blocking structure 14. Thus, the original thickness of the blocking structure 14 in natural state will not affect an assembled height of the flip-chip LED 10.

The flip-chip LED 10 described above can be manufactured in following steps.

A substrate 11 is provided, and a circuit layer 12 is formed on the substrate 11. The circuit layer 12 includes a first electrode 121, a second electrode 122 separated and electrically insulated from the first electrode 121, and metal shims 15 formed on top surfaces of the first electrode 121 and the second electrode 122 respectively. The metal shims 15 are arranged corresponding to a positive electrode 131 and a negative electrode 132 of the LED chip 13. The substrate 11 has a shape of a flat plate, and is made of silicon wafer.

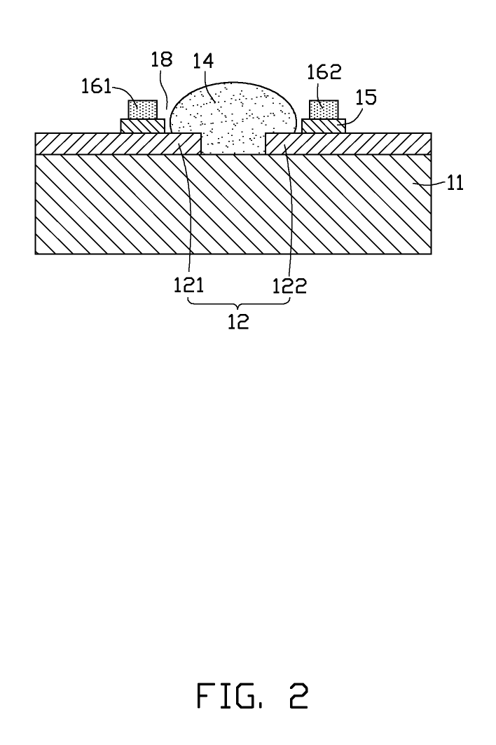

Referring to FIG. 2, a mass of colloidal, electrically insulating material is dropped on the substrate 11 between the first electrode 121 and the second electrode 122 of the circuit layer 12, so the blocking structure 14 is formed. In this embodiment, the colloidal, electrically insulating material is colloidal, high molecular polymer, such as sodium polyacrylate, polyacrylamide, carrageenan and gelatin et al. A bottom end of the blocking structure 14 contacts the substrate 11, and a top end of the blocking structure 14 is slightly higher than top surfaces of the first solder 161 and the second solder 162. The blocking structure 14 in the natural state as shown in FIG. 2 is generally semispherical.

The positive electrode 131 and the negative electrode 132 of the LED chip 13 are brought to contact with the first solder 161 and the second solder 162 respectively, wherein the blocking structure 14 is compressed between the LED chip 13 and the substrate 11. Then the first and second solders 161, 162 are heated to melt whereby the first and second solders 161, 162 securely and electrically connect the positive and negative electrodes 131, 132 and the shims 15 and the first and second electrodes 121, 122 together after the melted first and second solders 161, 162 are cooled and solidified. Thus, the flip-chip LED 10 is formed. The blocking structure 14 made of electrically insulating material can block a path between the first solder 161 and the second solder 162, thereby preventing the melted solders 161, 162 from overflowing to reach other to cause a short circuit between the positive electrode 131 and the negative electrode 132. In addition, the blocking structure 14 made of colloidal material can be depressed to deform when the LED chip 13 is mounted onto the first and second solders 161, 162, without affecting an assembled height of the flip-chip LED 10.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A flip-chip light emitting diode, comprising:
a substrate;
a circuit layer formed on the substrate, the circuit layer comprising a first electrode and a second electrode separated and electrically insulated from the first electrode, the first and second electrodes being on a top surface of the substrate;
an LED chip arranged on the circuit layer, the LED chip comprising a positive electrode and a negative electrode on a bottom surface thereof, the positive electrode and the negative electrode being in electrical connection to the first electrode and the second electrode of the circuit layer by solder, respectively; and
a blocking structure located between the positive electrode and the negative electrode, the blocking structure being made of elastic and electrically insulating material.

2. The flip-chip light emitting diode of claim 1, wherein the blocking structure is made of colloidal material.

3. The flip-chip light emitting diode of claim 2, wherein the blocking structure is arranged and compressed between the LED chip and the substrate, a thickness of the blocking structure at the compressed state is less than that of the blocking structure before it is compressed and in a natural state.

4. The flip-chip light emitting diode of claim 2, wherein the blocking structure is made of colloidal high molecular polymer.

5. The flip-chip light emitting diode of claim 4, wherein the blocking structure is made of one of odium polyacrylate, polyacrylamide, carrageenan and gelatin.

6. The flip-chip light emitting diode of claim 1, wherein the circuit layer further comprises metal shims formed on top surfaces of the first electrode and the second electrode respectively, the metal shims are arranged corresponding to the positive electrode and the negative electrode of the LED chip, and the metal shims are adapted for positioning and supporting the LED chip.

7. The flip-chip light emitting diode of claim 1, wherein a room is defined among the LED chip, the circuit layer and the substrate, and the blocking structure is in the room.

8. A method for making a flip-chip light emitting diode, comprising:
providing a substrate with a circuit layer formed thereon, the circuit layer comprising a first electrode and a second electrode separated and electrically insulated from the first electrode, the first and second electrodes being on a top surface of the substrate, first and second solders being respectively located on the first and second electrodes;
disposing a blocking structure made of elastic, electrically insulating material on the substrate and between the first electrode and the second electrode and between the first and second solders;
arranging an LED chip which comprises a positive electrode and a negative electrode on a bottom surface thereof on the first and second electrodes, the positive electrode contacting the first solder and the negative electrode contacting the second solder, the blocking structure being compressed between the LED chip and the substrate;
heating the first and second solders to become melted state and then cooling the first and second solders whereby the first solder electrically connects the first electrode and the positive electrode together and the second solder electrically connects the second electrode and the negative electrode together.

9. The method of claim 8, wherein the first and second electrodes each have a metal shim on a top surface thereof and the first and second solders are on the metal shims, respectively, and wherein the metal shims are positioned corresponding to the positive electrode and the negative electrode of the LED chip, and used for positioning and supporting the LED chip on the substrate.

10. The method of claim 8, wherein the blocking structure is made of colloidal, high molecular polymer.

11. The method of claim 10, wherein the blocking structure is made of one of odium polyacrylate, polyacrylamide, carrageenan and gelatin.

12. The method of claim 8, wherein the blocking structure sits between the LED chip and the substrate, a thickness of the blocking structure when it is compressed between the LED chip and the substrate is less than that of the blocking structure when it is in a natural state before the LED chip is arranged on the first and second electrodes.

13. The method of claim 12, wherein the blocking structure is hemispherical in shape in the natural state, and is ellipsoidal in shape when it is compressed between the LED chip and the substrate.
